(19) United States
(12) Patent Application Publication
(10) Pub. No.: US 2025/0192518 A1
(43) Pub. Date: Jun. 12, 2025

(54) SEMICONDUCTOR LASER

(71) Applicant: Lumentum Operations LLC, San Jose, CA (US)

(72) Inventor: Atsushi NAKAMURA, Komoro (JP)

(21) Appl. No.: 18/745,458

(22) Filed: Jun. 17, 2024

(30) Foreign Application Priority Data
Dec. 6, 2023 (JP) 2023-205737
Mar. 22, 2024 (JP) 2024-046659

(51) Int. Cl. H01S 5/12; H01S 5/042; H01S 5/22

(52) U.S. Cl. CPC H01S 5/1206; H01S 5/04256; H01S 5/22

(57) ABSTRACT

Provided is a semiconductor laser having excellent characteristics. The semiconductor laser includes: first and second-conductivity-type semiconductor layers; first and second electrodes electrically connected to the first or second-conductivity-type semiconductor layer; a diffraction grating layer; an insulating film placed in a part of a space between the second electrode and the second-conductivity-type semiconductor layer; a mesa structure; and first and second regions in a direction in which the mesa structure stretches. A first diffraction grating region in the diffraction grating layer of the first region and a second diffraction grating region in the diffraction grating layer of the second region form a resonator. The first region has a normalized coupling coefficient higher than a normalized coupling coefficient of the second region. In the first region, an electric current supplied from the second electrode to the mesa structure per unit area is smaller than in the second region.

### CROSS-REFERENCE TO RELATED APPLICATIONS

This patent application claims priority to Japanese Patent Application No. 2024-046659, filed on Mar. 22, 2024, and to Japanese Patent Application No. 2023-205737, filed on Dec. 6, 2023. The disclosure of the prior applications are considered part of and are incorporated by reference into this patent application.

### TECHNICAL FIELD

The present disclosure relates generally to a semiconductor laser.

### BACKGROUND

Semiconductor lasers are widely used as a light source for optical communications. A distributed feedback semiconductor laser (DFB laser) is one type of a semiconductor laser. The DFB laser includes a diffraction grating. Further, the diffraction grating can include a structure in which a phase shift portion for characteristic improvement. A stable single-wavelength operation can be obtained by forming an anti-reflection film (low reflection film) on both facets of the semiconductor laser and arranging a λ/4 shift portion in the diffraction grating. Two regions different from each other in reflectance with respect to a Bragg-reflected light beam in a resonator direction can be arranged so that output from one facet is increased.

### SUMMARY

A structure can combine regions high in reflectance and low in reflectance with respect to a Bragg wavelength. An electrode to which a driving current is injected can be arranged so as to stretch across the two regions different from each other in reflectance. Accordingly, the two regions differing in reflectance are have approximately the same injection current density. The region high in reflectance is low in photon density compared to the region low in reflectance, and is accordingly high in carrier density and low in refractive index. The region high in reflectance is also large in gain. Being low in refractive index invites deterioration of side-mode suppression ratio (SMSR) and a drop in yield. Being large in gain causes a drop in light extraction efficiency and degradation of relative noise intensity characteristics.

An object of the present invention is to provide a semiconductor laser having excellent characteristics.

Some implementations described herein include a semiconductor laser that comprises: a first-conductivity-type semiconductor layer; an active layer formed on the first-conductivity-type semiconductor layer; a second-conductivity-type semiconductor layer formed on the active layer; a first electrode electrically connected to the first-conductivity-type semiconductor layer; a second electrode electrically connected to the second-conductivity-type semiconductor layer; a diffraction grating layer placed on one of the first-conductivity-type semiconductor layer side or the second-conductivity-type semiconductor layer side when viewed from the active layer; an insulating film placed in a part of a space between the second electrode and the second-conductivity-type semiconductor layer; a mesa structure including at least one of the active layer or the second-conductivity-type semiconductor layer; and a first region and a second region in a direction in which the mesa structure stretches. The diffraction grating layer of the first region includes a first diffraction grating region. The diffraction grating layer of the second region includes a second diffraction grating region. The first diffraction grating region and the second diffraction grating region form a resonator. The first region has a normalized coupling coefficient higher than a normalized coupling coefficient of the second region. In the first region, an electric current supplied from the second electrode to the mesa structure per unit area is smaller than in the second region.

### BRIEF DESCRIPTION OF THE DRAWINGS

FIG. 1 is a top view for illustrating a semiconductor laser according to a first example implementation of the present disclosure.

FIG. 2 is a schematic sectional view taken along the line II-II of the semiconductor laser illustrated in FIG. 1.

FIG. 3 is a schematic sectional view taken along the line III-III of the semiconductor laser illustrated in FIG. 1.

FIG. 4 is another top view of the semiconductor laser according to the first example implementation.

FIG. 5 is a top view of a semiconductor laser according to Modification Example 1 of the first example implementation.

FIG. 6 is a top view of a semiconductor laser according to Modification Example 2 of the first example implementation.

FIG. 7 is a schematic sectional view of a semiconductor laser according to a second embodiment of the present disclosure.

FIG. 8 is a top view of the semiconductor laser according to the second example implementation.

FIG. 9 is a schematic sectional view of a semiconductor laser according to a third example implementation of the present disclosure.

FIG. 10 is a top view of the semiconductor laser according to the third example implementation.

FIG. 11 is a top view of a semiconductor laser according to a fourth example implementation of the present disclosure.

FIG. 12 is a schematic sectional view taken along the line XII-XII of the semiconductor laser illustrated in FIG. 11.

FIG. 13 is another top view of a semiconductor laser according to the fourth example implementation.

FIG. 14 is a top view of a semiconductor laser according to a fifth example implementation of the present disclosure.

FIG. 15 is a schematic sectional view taken along the line XV-XV of the semiconductor laser illustrated in FIG. 14.

FIG. 16 is a schematic sectional view taken along the line XVI-XVI of the semiconductor laser illustrated in FIG. 14.

FIG. 17 is a schematic sectional view taken along the line XVII-XVII of the semiconductor laser illustrated in FIG. 14.

FIG. 18 is another top view of the semiconductor laser according to the fifth example implementation.

FIG. 19 is a top view of a semiconductor laser according to a sixth example implementation of the present disclosure.

FIG. 20 is a schematic sectional view taken along the line XX-XX of the semiconductor laser illustrated in FIG. 19.

FIG. 21 is another top view of the semiconductor laser according to the sixth example implementation.

### DETAILED DESCRIPTION

A specific and detailed description is given below on embodiments of the present invention with reference to the drawings. Members denoted by the same reference symbol throughout the drawings have the same or an equivalent function, and a repetitive description on the members is omitted. Note that sizes of graphics are not always to scale.

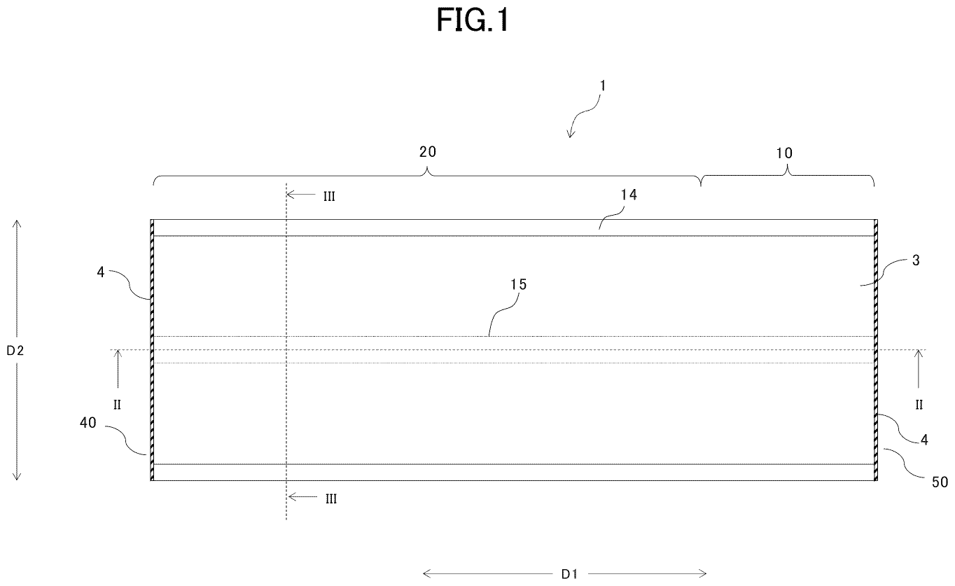

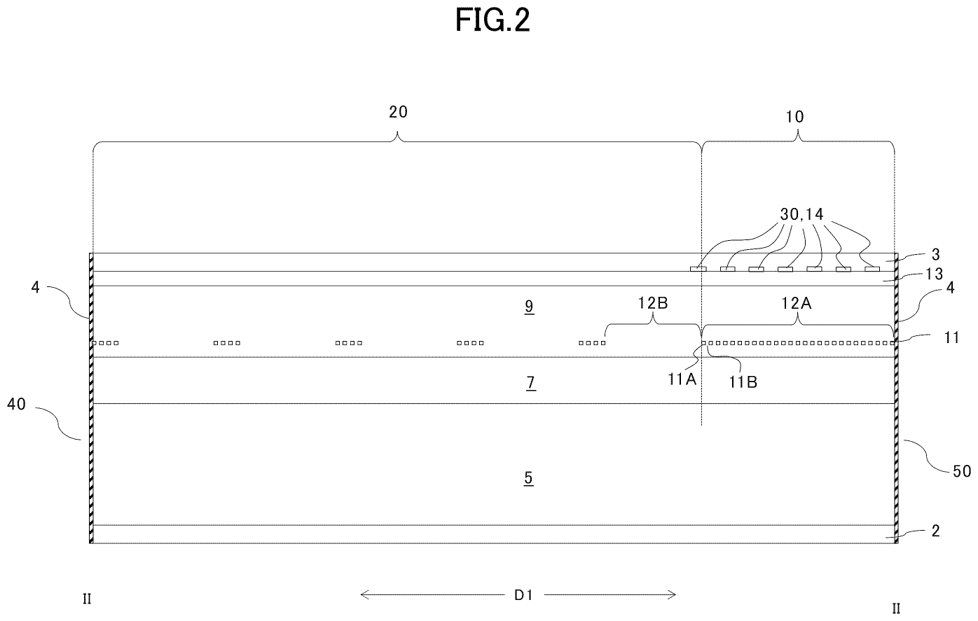

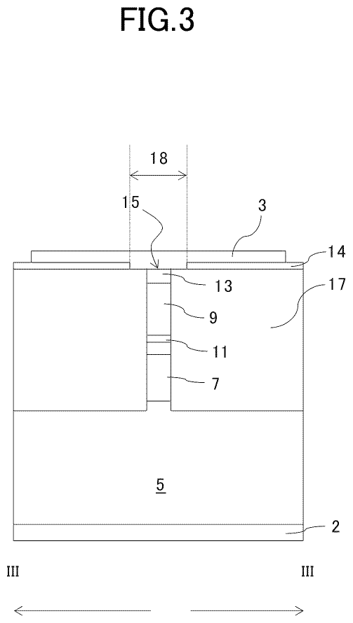

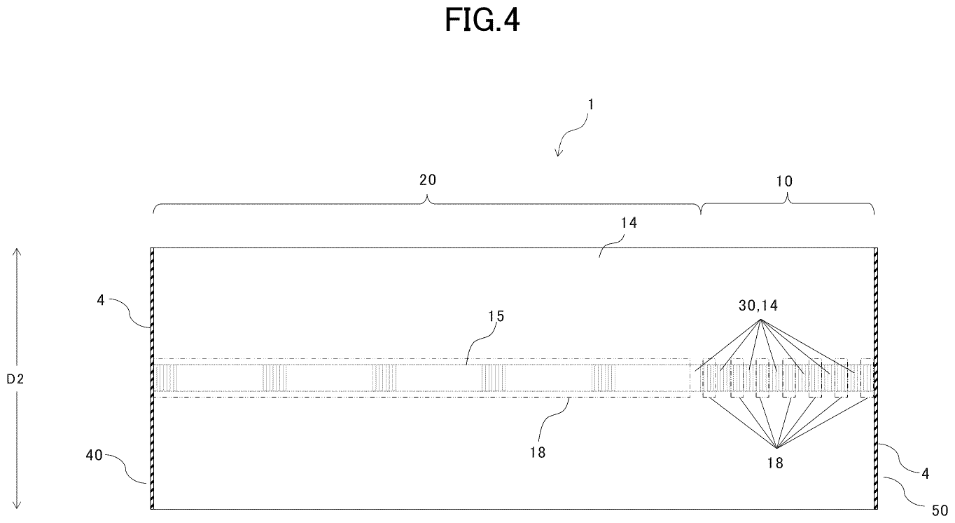

FIG. 1 is a top view for illustrating a semiconductor laser 1 according to a first example implementation of the present disclosure. FIG. 2 shows a schematic sectional view taken along the line II-II of FIG. 1. FIG. 3 shows a schematic sectional view taken along the line III-III of FIG. 1. FIG. 4 is a top view for illustrating the semiconductor laser 1, and is an explanatory view for illustrating a position of each region included in the semiconductor laser 1. The semiconductor laser 1 may include a first electrode 2 on a back surface thereof and a second electrode 3 on a front surface thereof. The first electrode 2 and the second electrode 3 may be metal layers. A light beam may be emitted from a front facet 40 (facet on the left side of FIG. 1 and FIG. 2) through injection of electric currents between the first electrode 2 and the second electrode 3. The first electrode 2 may be an electrode that is electrically connected to a first-conductivity-type semiconductor layer described later. The second electrode 3 may be an electrode that is electrically connected to a second-conductivity-type semiconductor layer described later. A low-reflection facet coating film 4 may be formed on each of facets in a direction in which a mesa structure described later stretches (hereinafter referred to as “first direction D1”), that is, the front facet 40 (facet on the left side of FIG. 1 and FIG. 2) and a rear facet 50 (facet on the right side of FIG. 1 and FIG. 2). A reflectance of the low-reflection facet coating film 4 may be 1% or less.

The semiconductor laser 1 may have a semiconductor multilayer structure including the first-conductivity-type semiconductor layer, an active layer, and the second-conductivity-type semiconductor layer, which may be grown in the stated order. In the first example implementation, semiconductor layers that are a core layer 7, a cladding layer 9 of a second-conductivity-type, and a contact layer 13 of the second-conductivity-type may be grown in the stated order on a substrate 5 of a first-conductivity-type. The substrate 5 corresponds to the first-conductivity-type semiconductor layer. Another first-conductivity-type semiconductor layer may be formed on the substrate 5. The core layer 7 may be semiconductor layers including at least the active layer. For example, the core layer 7 may be semiconductor layers obtained by growing an optical confinement layer of the first-conductivity-type, the active layer which may be formed from a multiple quantum well layer of an “i” type, and an optical confinement layer of the second-conductivity-type in order from the substrate 5 side to the cladding layer 9 side of the second-conductivity-type. The core layer 7 may include layers other than those semiconductor layers. The active layer may be an n-type semiconductor layer. In the first example implementation, the cladding layer 9 and the contact layer 13 form the second-conductivity-type semiconductor layer. A diffraction grating layer 11 may be formed in the cladding layer 9 of the second-conductivity-type. The semiconductor laser 1 may be a DFB laser. The first-conductivity-type and the second-conductivity-type here may be the n-type and the p-type, respectively, but may be switched with each other. As illustrated in FIG. 3, the semiconductor multilayer including the above-mentioned layers may have a mesa structure 15. Here, a part of the substrate 5 may be included in the mesa structure 15, as well as the core layer 7, the cladding layer 9, and the contact layer 13. The mesa structure 15 stretches in a direction from which light may be taken out. The mesa structure 15 may be covered on each side with a semi-insulating semiconductor buried layer 17. The buried layer 17 may be a multilayer of p-type and n-type semiconductor layers. The dotted line of FIG. 1 indicates positions of boundaries between the mesa structure 15 and the buried layer 17. The mesa structure 15 may have a width constant in a direction perpendicular to the first direction D1 in plan view (hereinafter referred to as “second direction D2”).

The semiconductor laser 1 may include an insulating film 14. The insulating film 14 may cover a surface of the semiconductor laser 1 except some portions. The insulating film 14 may be a film of, for example, silicon oxide, silicon nitride, or a resin. The insulating film 14 may include, in a part of a space above the mesa structure 15, one or more opening regions in which the second electrode 3 and the second-conductivity-type semiconductor layer may be in contact with each other. The second electrode 3 and the contact layer 13 of the second-conductivity-type may be physically and electrically connected to each other via the opening regions, and an electric signal may be applied (an electric current may be injected) to the active layer via the second-conductivity-type semiconductor layer. The opening regions may be holes for electrically connecting the second electrode 3 and the contact layer 13 of the second-conductivity-type to each other and, accordingly, may be hereinafter also referred to as “through-holes 18.” In the first example implementation, the through-holes 18 may be aligned in the first direction D1. Each of the through-holes 18 may have a width (a length in the second direction D2) wider than a width of the mesa structure 15. However, the width of each of the through-holes 18 may be the same as, or narrower than the mesa width. Details of the through-holes 18 are described later.

The diffraction grating layer 11 may include a plurality of first refractive index regions 11A and a plurality of second refractive index regions 11B. Specifically, the diffraction grating layer 11 may be of a floating type, and may be formed of, in sectional view, regions having a first refractive index that is different from a refractive index of the cladding layer 9 of the second-conductivity-type, and regions having a second refractive index in which the cladding layer 9 of the second-conductivity-type may be arranged. That is, the diffraction grating layer 11 may have a structure in which first refractive index regions 11A and second refractive index regions 11B that have the same length are alternately arranged. In this case, the first refractive index is higher than the second refractive index, but the second refractive index may be higher than the first refractive index.

A region in the diffraction grating layer 11 in which the first refractive index regions 11A and the second refractive index regions 11B may have the same length and are alternately arranged may be referred to as “diffraction grating region 12A.” Meanwhile, a region in the diffraction grating layer 11 in which only the first refractive index region 11A or only the second refractive index region 11B is arranged is may be referred to as “non-diffraction grating region 12B.” In the first example implementation, the non-diffraction grating region 12B may be formed of the second refractive index region 11B. The diffraction grating region 12A in the first example implementation may have a uniform diffraction grating structure in which the first refractive index regions 11A and the second refractive index regions 11B have the same length and are alternately arranged in the first direction D1. The Bragg wavelength of this diffraction grating structure corresponds to a 1.3-μm band, but other Bragg wavelengths such as a 1.55-μm band may be used.

As illustrated in FIG. 2, the semiconductor laser 1 may include two regions. On the rear facet 50 side, a first region 10 including one of diffraction grating regions 12A may be placed. On the front facet 40 side, a second region 20 in which a plurality of diffraction grating regions 12A and a plurality of non-diffraction grating regions 12B are alternately arranged may be placed. Here, the diffraction grating regions 12A and the non-diffraction grating regions 12B may be arranged so that the light beam having the Bragg wavelength transmitted from the first region 10 may be reflected into the second region 20. In order to strongly reflect a light beam having a specific wavelength (Bragg wavelength), adjustment of lengths (diffraction grating periods) of the first refractive index regions 11A and the second refractive index regions 11B may be required. Further, a relationship between the diffraction grating period and the Bragg wavelength may be dependent on an effective refractive index. In the first example implementation, the first region 10 may have a larger effective refractive index than that of the second region 20. That may be because, when the second region 20 is viewed as a whole, the number of regions having no diffraction grating structure (regions being the non-diffraction grating regions 12B) is large, and hence the effective refractive index may be decreased by this amount. In consideration of a difference between the average effective refractive index of the first region 10 and the average effective refractive index of the second region 20, the diffraction grating regions 12A and the non-diffraction grating regions 12B to be arranged in the second region 20 may be determined. Here, the diffraction grating period of the diffraction grating region 12A arranged in the second region 20 may be different from or the same as the diffraction grating period of the diffraction grating region 12A arranged in the first region 10. In the case of employing the same diffraction grating period, a length in the first direction D1 of each of the plurality of diffraction grating regions 12A and the plurality of non-diffraction grating regions 12B and intervals of both of those regions may be adjusted so that the average diffraction grating period of the entire second region 20 reflects the light beam having the desired Bragg wavelength. In the following, when particular distinction may be required, the diffraction grating region 12A included in the first region 10 may be referred to as “first diffraction grating region,” and the diffraction grating region 12A included in the second region 20 may be referred to as “second diffraction grating region.” The diffraction grating regions 12A and the non-diffraction grating regions 12B included in the second region 20 may have different lengths in the first direction D1. It may be preferred that, for example, under a condition of causing reflection at a desired Bragg wavelength, each length be different so as to suppress high-order diffraction backscattering with respect to the Bragg wavelength.

In order to obtain a high single-wavelength characteristic, it may be desired to form a resonator by the first region 10 and the second region 20. In order to form the resonator by the first region 10 and the second region 20, it may be required that a phase of the diffraction grating region of the first region 10 and a phase of the diffraction grating region of the second region 20 be π-shifted. Here, the phase of the diffraction grating region refers to a phase of the diffraction grating structure. For example, when the first region 10 and the second region 20 have the same effective refractive index, it may be only required that the phase of the second diffraction grating region (diffraction grating region 12A of the second region 20) be simply π-shifted with respect to the phase of the first diffraction grating region (diffraction grating region 12A of the first region 10). However, in the first example implementation, the first region 10 and the second region 20 may have different effective refractive indices. Accordingly, the phase of the second diffraction grating region may be required to be different from a phase obtained by π-shifting the phase of the first diffraction grating region. In the first example implementation, the phase of the first diffraction grating region and the phase of the second diffraction grating region may not be π-shifted, but the resonator may be formed by the first region 10 and the second region 20. Moreover, in the first example implementation, the low-reflection facet coating film 4 may be formed on both facets, and hence a very high single-wavelength characteristic may be achieved.

In the first example implementation, a normalized coupling coefficient κ1L1 of the first region 10 may be larger than a normalized coupling coefficient κ2L2 of the second region 20. A coupling coefficient κ may be determined in accordance with the semiconductor multilayer and the diffraction grating structure. Here, a coupling coefficient κ1 of the first region 10 and a coupling coefficient κ2 of the second region 20 may be not the same due to the difference in effective refractive index, for example. However, this difference may be small, and the dominant cause of the difference in the normalized coupling coefficient between the first region 10 and the second region 20 may be the length in the first direction D1 of the diffraction grating region 12A included in each of the regions. Here, a length L1 of the first region 10 may be a length of the first diffraction grating region in the first direction D1. A length L2 of the second region 20 may be a total length of the plurality of second diffraction grating regions. That is, the length L2 may be a total length in the first direction D1 of the plurality of diffraction grating regions 12A included in the second region 20. The non-diffraction grating region 12B does not reflect the light beam having the Bragg wavelength, and hence a coupling coefficient κ of the non-diffraction grating region 12B may be practically regarded as 0. Accordingly, the length L2 of the second region 20 contributing to the normalized coupling coefficient KL becomes the total length of the regions in which the plurality of second diffraction grating regions are arranged. The normalized coupling coefficient κ1L1 of the first region 10 may be larger than the normalized coupling coefficient κ2L2 of the second region 20, and hence the light output intensity of the light beam output from the front facet 40 becomes larger than the light output intensity of the light beam output from the rear facet 50. When the normalized coupling coefficients of the first region 10 and the second region 20 are the same value, the light output intensities of the light beams output from the front facet 40 and the rear facet 50 are the same. In the present disclosure, the total length of the regions in which the plurality of second diffraction grating regions are arranged may be set to be shorter than the length of the region in which the first diffraction grating region may be arranged so that the intensity of the light beam output from the front facet 40 may be increased. The “front” and the “rear” as used here may be merely naming used for the sake of convenience, and a facet having a larger light output may be just referred to as the front facet. In a general optical communication, a larger light intensity may be preferred, and a light beam from the front facet may be used for the communication. Further, the total length in the first direction D1 of the plurality of second diffraction grating regions may be shorter than the total length of the plurality of non-diffraction grating regions 12B. With this structure, the effect of increasing the light output from the front side by decreasing the coupling coefficient κ2 of the second region 20 may be enhanced. Here, it may be preferred that κ1L1 be 60% or more (that is, κ2L2 be 40% or less) with respect to the normalized coupling coefficient of the entire semiconductor laser 1.

Here, a resonator length of the semiconductor laser 1 may be a total length in the first direction D1 of the first region 10 and the second region 20. In the first example implementation, the resonator length corresponds substantially to a length between the front facet 40 and the rear facet 50. The first example implementation also aims to increase the light output intensity of the light beam output from the front facet 40 so as to be larger than the light output intensity of the light beam output from the rear facet 50. For this purpose, it may be preferred that the first region 10 (more strictly, the first diffraction grating region) be located on the rear side. For example, it may be preferred that the first diffraction grating region be arranged in a region within 40% or less of the resonator length from a rear end portion (in this case, the rear facet 50) of the resonator. That is, the length of the first diffraction grating region in the direction in which the mesa structure extends may be preferably equal to or smaller than 40% of the length of the entire diffraction grating layer, more preferably equal to or smaller than 30% thereof. However, when κ1L1 is smaller than 1, a threshold value of oscillation may be increased, which may not be preferred in the viewpoint of power consumption. Accordingly, κ1L1 may be preferably set to 1 or more, more preferably 1.5 or more.

FIG. 4 is a top view of the semiconductor laser 1, and may be an explanatory view for illustrating positions of the opening regions (through-holes 18). Illustration of the second electrode 3 is omitted from FIG. 4 for an explanatory purpose. FIG. 4 is also a view as seen through the diffraction grating layer 11 as if the diffraction grating layer 11 is transparent. The dot-dot-dash lines indicate the positions of the through-holes 18.

The through-holes 18 may be openings provided in the insulating film 14. The through-holes 18 may be placed only in a part of a top surface of the mesa structure 15 in the first region 10. In other words, the through-holes 18 may be discretely placed in the first region 10. In the first region 10, high resistance elements 30 may be placed in regions other than the opening regions (hereinafter also referred to as “non-opening regions”) in a region immediately above the mesa structure 15. That is, the high resistance elements 30 may be placed in a part of the top surface of the mesa structure 15 in the first region 10. The phrase “high resistance” means that an electric resistance is high compared to the contact layer 13. In the first example implementation, the high resistance elements 30 may be a part of the insulating film 14. However, a material of the high resistance elements 30 and a material of regions of the insulating film 14 other than the high resistance elements 30 may differ from each other. Examples of the other material are given later. The high resistance elements 30 may be higher in electric resistance than the contact layer 13 of the second-conductivity-type. In the opening regions which are regions above the mesa structure 15 and in which the insulating film 14 may not be placed, the second electrode 3 and the contact layer 13 of the second-conductivity-type may be electrically and physically in contact with each other. A shape of each of the through-holes 18 may be quadrangular in plan view, but is not limited thereto. For example, the through-holes 18 may each may have a shape of a quadrangle with rounded corners.

As described above, the normalized coupling coefficient κ1L1 of the first region 10 may be higher than the normalized coupling coefficient κ2L2 of the second region 20. A photon density of the first region 10 may be accordingly lower than a photon density of the second region 20. Carrier consumption due to stimulated emission may be greater when the photon density is higher. Accordingly, in a case in which the first region 10 and the second region 20 are equal to each other in injection current density, a carrier density of the first region 10 may be higher than a carrier density of the second region 20. In the first example implementation, the first region 10 and the second region 20 may have an equal injection current density because the second electrode 3 is placed so as to stretch across the first region 10 and the second region 20. Having a higher carrier density, the first region 10 may be lower in refractive index and may be larger in gain. A drop in refractive index invites deterioration of SMSR characteristics, and an increase in gain causes a drop in efficiency of light output from the front facet 40 and degradation of relative noise intensity characteristics. The present disclosure deals with this by setting an electric current supplied from the second electrode 3 to the mesa structure 15 per unit area smaller in the first region 10 than in the second region 20. In the first example implementation, the electric current per unit area may be set smaller in the first region 10 than in the second region 20 by limiting a region to which an electric current may be injected in the first region 10. The injection current density of the first region 10 may be thus set lower compared to the second region 20, to thereby keep the carrier density of the first region 10 from increasing. In order to limit the region to which an electric current is injected, the through-holes 18 of the first region 10 may be placed only in a part of, instead of the entirety of, the region immediately above the mesa structure 15. In regions in which no through-holes 18 are placed, the high resistance elements 30 may be placed. In other words, in the top surface of the mesa structure 15 in the first region 10, opening regions (the through-holes 18) and non-opening regions (the high resistance elements 30) may be alternately arranged along the first direction D1. No electric current may be injected to the non-opening regions, and the overall carrier density of the first region 10 can accordingly be decreased.

A proportion at which the opening regions (through-holes 18) occupy the region immediately above the mesa structure 15 in the first region 10 may be preferred to be 60% or less. The proportion at which the opening regions occupy the region immediately above the mesa structure 15 may be hereinafter referred to as “opening ratio.” A more preferred opening ratio may be 20% or more and 50% or less. The term “opening ratio” may be read as a ratio of planar dimensions of regions in which the second electrode 3 and the second-conductivity-type semiconductor layer (contact layer 13) are in contact with each other (energized regions) to the entire planar dimensions of the top surface of the mesa structure 15 in the first region 10. In FIG. 2, the second region 20 may include a region in which the high resistance elements 30 are placed, near a place at which the second region 20 may be connected to the first region 10. This region, however, may be sufficiently small compared to the opening regions of the second region 20 on the whole, and hence may have little influence on the carrier density. In the first example implementation, the opening ratio of the first region 10 may be smaller than the opening ratio of the second region 20, to thereby enable reducing the influence of the difference in carrier density due to the difference in normalized coupling coefficient KL.

In the first example implementation, the plurality of through-holes 18 and the plurality of high resistance elements 30 that are provided in the first region 10 may have the same length in the first direction D1, but may be not limited thereto and may have different lengths. However, it may be desired to arrange the plurality of through-holes 18 discretely in order to ensure that the injection current of the first region 10 is uniform. A desired minimum length between the plurality of through-holes 18 in the first direction D1 may be ⅕ or less of the length of the first region 10.

In the first example implementation, the first electrode 2 and the second electrode 3 may be each integrally formed so as to stretch across the first region 10 and the second region 20, but may be not limited thereto. As long as electric currents may be injected to electrodes in the first region 10 and the second region 20 at the same injection current density, separate electrodes may be provided for the first region 10 and for the second region 20.

The semiconductor laser 1 according to the first example implementation achieves both of high wavelength uniformity and high power characteristics in output from the front facet 40 by forming a resonator from the first region 10 having the normalized coupling coefficient κ1L1 which may be high and the second region 20 having the normalized coupling coefficient κ2L2 which may be lower than the normalized coupling coefficient κ1L1. The semiconductor laser 1 also achieves excellence in SMSR characteristics and relative noise intensity characteristics by setting the opening ratio of the through-holes 18 of the first region 10 lower than the opening ratio of the through-holes 18 of the second region 20.

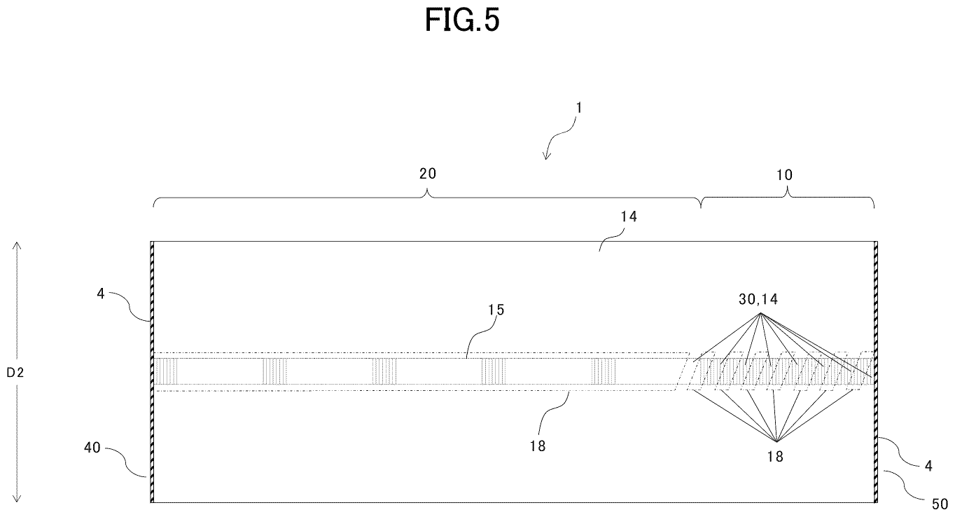

FIG. 5 is a top view of the semiconductor laser 1 according to Modification Example 1 of the first example implementation, and is an explanatory view for illustrating a mode of the through-holes 18. A difference from the first example implementation is a shape of the through-holes 18 and the high resistance elements 30. In Modification Example 1, the through-holes 18 each may have a parallelogram shape in plan view. In other words, sides forming the through-holes 18 and the high resistance elements 30 may be arranged so as to be inclined with respect to the first direction D1 in which light resonates. Angles of inclination are all constant here, but may be not limited thereto and may differ from one another.

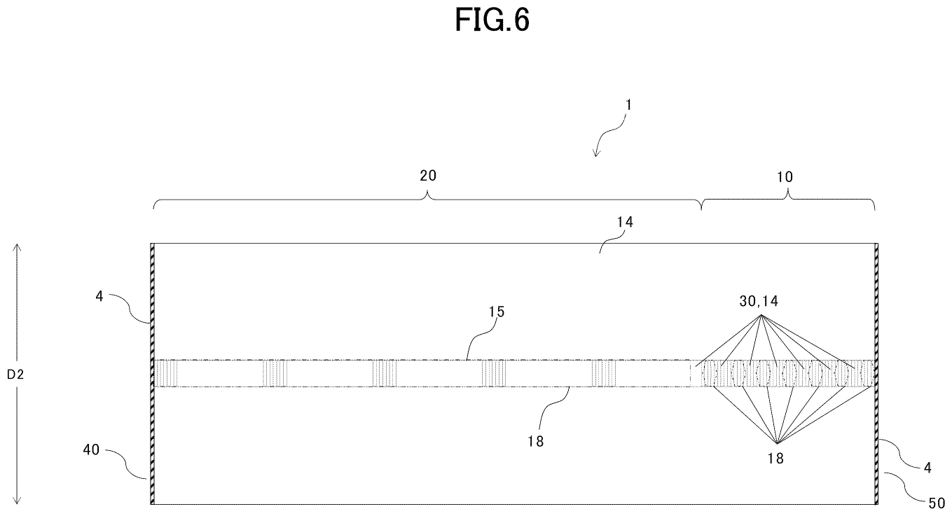

FIG. 6 is a top view of the semiconductor laser 1 according to Modification Example 2 of the first example implementation, and is an explanatory view for illustrating a mode of the through-holes 18. A difference from the first example implementation is a shape of the through-holes 18 and the high resistance elements 30. Widths of the respective through-holes 18 may be substantially the same in the second direction D2 of the mesa structure 15. The through-holes 18 in the first region 10 may be hexagonal. Thus, the shape of each of the through-holes 18 may be quadrangular, hexagonal, or other polygonal shapes, and may also be circular or elliptical. A combination of those shapes may also be used. The effects of the present disclosure may be obtained as long as the opening ratio of the first region 10 is lower than the opening ratio of the second region 20.

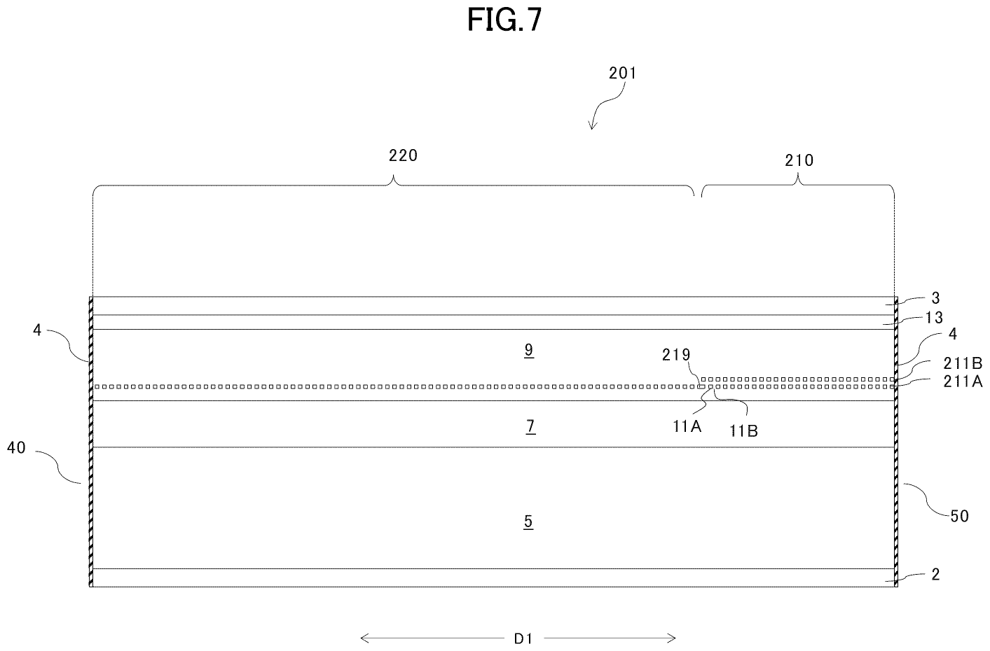

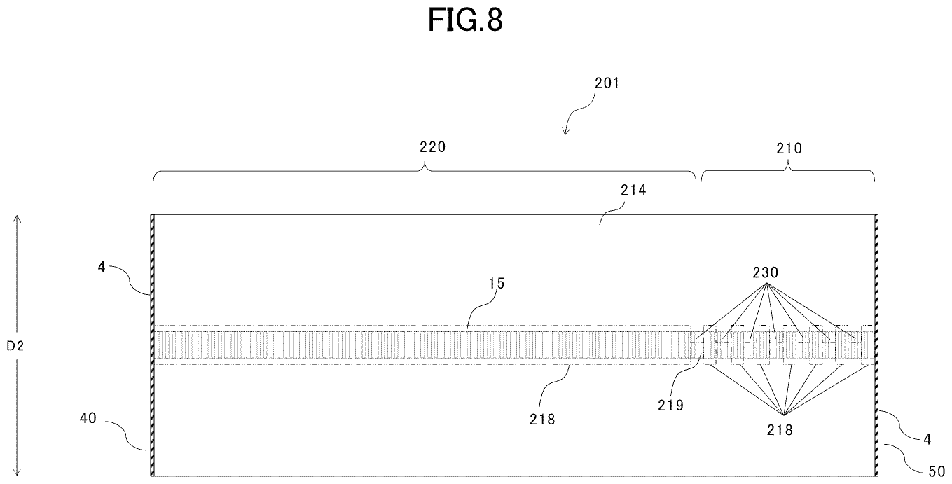

FIG. 7 is a schematic sectional view taken along the first direction D1 of a semiconductor laser 201 according to a second example implementation of the present disclosure, and corresponds to a schematic sectional view taken along the line II-II of FIG. 1. FIG. 8 is a top view of the semiconductor laser 201, and is an explanatory view for illustrating a mode of opening regions (through-holes 218).

A semiconductor multilayer structure of the semiconductor laser 201 may be substantially the same as that of the semiconductor layer 1 according to the first example implementation, but may differ in the number of diffraction grating layers and in diffraction grating structure. In the second example implementation, a first region 210 may include two layers which may be a first diffraction grating layer 211A and a second diffraction grating layer 211B, with the first diffraction grating layer 211A being closer to the core layer 7 than the second diffraction grating layer 211B is. The cladding layer 9 may be placed between the first diffraction grating layer 211A and the second diffraction grating layer 211B. A second region 220, on the other hand, may include only the first diffraction grating layer 211A. A λ/4 phase shift portion 219 may be placed between the first region 210 and the second region 220. The λ/4 phase shift portion 219 may be placed in the second diffraction grating layer 211B as well. The first region 210 may have a uniform diffraction grating structure in which the first refractive index regions 11A and the second refractive index regions 11B may have the same length in the first direction D1 and may be alternately arranged, except for the phase shift portion 219. In the first region 210, the first refractive index regions 11A and the second refractive index regions 11B that are included in the first diffraction grating layer 211A may have the same length and the same phase as a length and a phase of the first refractive index regions 11A and the second refractive index regions 11B that are included in the second diffraction grating layer 211B. The second region 220 may have a uniform diffraction grating structure in which the first refractive index regions 11A and the second refractive index regions 11B have the same length in the first direction D1 and are alternately arranged, except for the phase shift portion 219. The first region 210 may include a first diffraction grating region formed from two diffraction grating layers (the first diffraction grating layer 211A and the second diffraction grating layer 211B). The second region 220 may include a second diffraction grating region formed from a single diffraction grating layer (the first diffraction grating layer 211A). The first diffraction grating region and the second diffraction grating region form a resonator with the phase shift portion 219 sandwiched therebetween.

The first region 210 is, because of the second diffraction grating layer 211B included therein, higher in coupling coefficient κ than the second region 220. In the second example implementation, the normalized coupling coefficient κ1L1 of the first region 210 may be higher than the normalized coupling coefficient κ2L2 of the second region 220 in order to set light intensity of light output from the front facet 40 higher than light intensity of light output from the rear facet 50. Here, “L1” represents an entire length of the first region 210 in the first direction D1. “L2” represents an entire length of the second region 220. The length L1 may be a half or less of an entire length of the semiconductor laser 201. That is, while the main cause of the difference in normalized coupling coefficient KL between the first region 10 and the second region 20 may be the difference in the total length of the diffraction grating regions 12A in the first example implementation, the main cause in the second example implementation may be the differences in the number of diffraction grating layers and in length between the first region 210 and the second region 220. The number of diffraction grating layers is not limited to two as long as the number of diffraction grating layers in the first region 210 is larger than that in the second region 220. For example, the number of diffraction grating layers of the first region 210 and the number of diffraction grating layers of the second region 220 may be three and two, respectively.

The second example implementation differs from the first example implementation also in the structure of high resistance elements 230. In the first example implementation, the high resistance elements 30 placed in the top surface of the mesa structure 15 of the first region 210 may be continuous in the second direction D2. In the second example implementation, on the other hand, widths of opening regions in a direction (the second direction D2) perpendicular, in plan view, to the direction (the first direction D1) in which the mesa structure 15 stretches may be wide in some portions and narrow in other portions. The high resistance elements 230 may be placed on each side of the portions in which the opening regions may have a narrow width. According to this structure, although an electric current injected from a part of the second electrode 3 that is located in the opening regions reaches below the high resistance elements 230 to inject the electric current there as well, an injection current density below the high resistance elements 230 may be lower than an injection current density below the opening regions (the through-holes 218). In the second region 220, on the other hand, the high resistance elements 230 may be placed only in the place at which the second region 220 may be connected to the first region 210, and an opening region (the through-holes 218) may be placed in most of the second region 220. In other words, in the first region 210, regions in which the top surface of the mesa structure 15 may have an opening entirely opened in the second direction D2 (the wide-width portions) and regions in which the top surface of the mesa structure 15 may have an opening partially opened in the second direction D2 (the narrow-width portions) may be alternately arranged. In the second region 220, on the other hand, an opening region (one of the through-holes 218) may be placed in an entire region immediately above the mesa structure 15. The opening ratio of the through-holes 218 of the first region 210 may be accordingly lower than the opening ratio of the second region 220. As a result, the injection current density of the first region 210 becomes lower than that of the second region 220, and the same effects as the effects of the first example implementation can accordingly be obtained.

It should be understood that the same effects may be obtained by applying the structures of the through-holes 18 and the high resistance elements 30 that may be shown in the first example implementation and the modification examples thereof to the semiconductor laser 201. Similarly, the structure of the high resistance elements 230 shown in the second example implementation may be combined with the first example implementation.

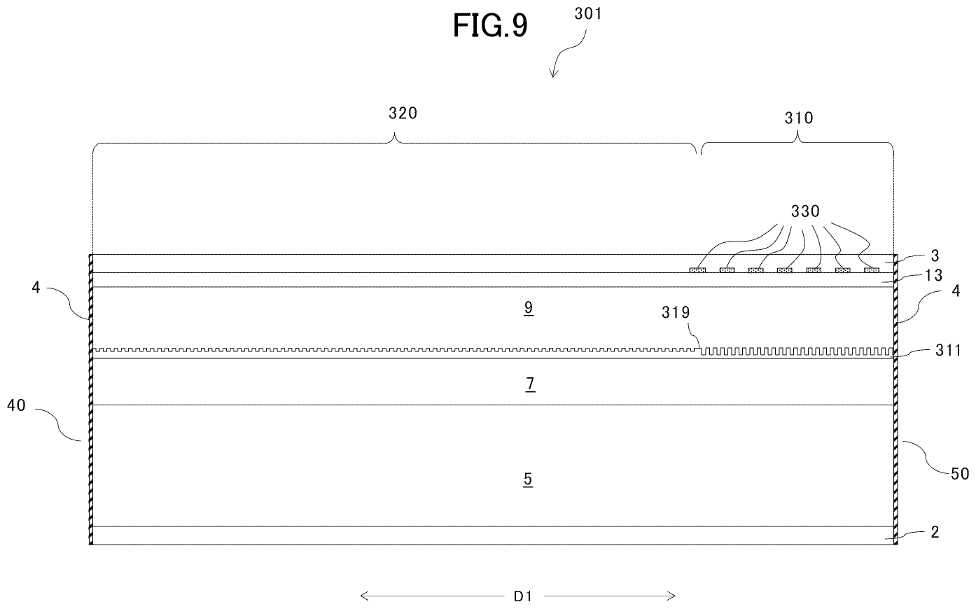

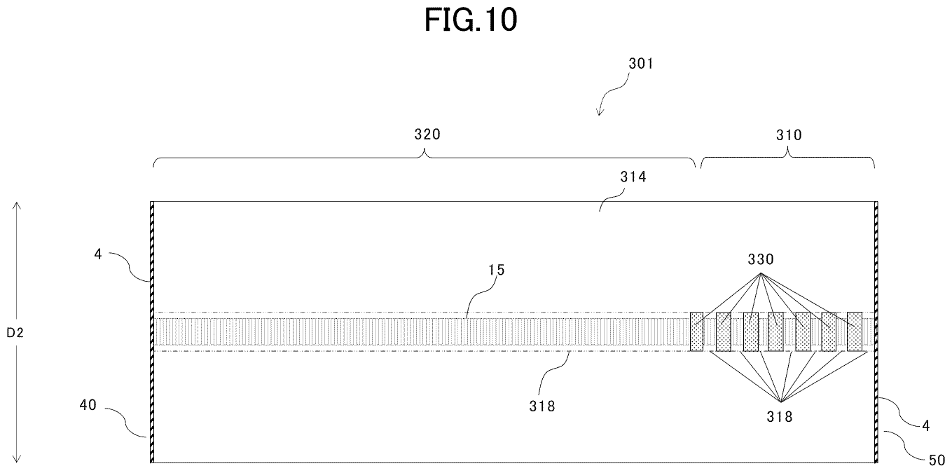

FIG. 9 is a schematic sectional view taken along the first direction D1 of a semiconductor laser 301 according to a third example implementation of the present disclosure, and corresponds to a schematic sectional view taken along the line II-II of FIG. 1. FIG. 10 is a top view of the semiconductor laser 301, and may be an explanatory view for illustrating a mode of opening regions (through-holes 318).

A semiconductor multilayer structure of the semiconductor laser 301 may be substantially the same as that of the semiconductor layer 1 according to the first example implementation, but differs in diffraction grating structure. In the third example implementation, a diffraction grating structure may be formed by forming convexities and concavities on a surface of a diffraction grating layer 311 placed on the core layer 7. The cladding layer 9 may be placed in regions of concavities. Regions of convexities correspond to the first refractive index regions 11A, and the regions of concavities correspond to the second refractive index regions 11B. A height of each convexity (a depth of each concavity) of the diffraction grating structure of a first region 310 may be greater than that in the diffraction grating structure of a second region 320. The height or the depth may be defined in a stacking direction in which semiconductor layers are grown. A λ/4 phase shift portion 319 may be placed between the first region 310 and the second region 320. The first region 310 may have a uniform diffraction grating structure in which the first refractive index regions 11A and the second refractive index regions 11B have the same length in the first direction and are alternately arranged. The second region 320 may have a uniform diffraction grating structure in which the first refractive index regions 11A and the second refractive index regions 11B may have the same length in the first direction and may be alternately arranged. The first region 310 may have a first diffraction grating region in which the diffraction grating structure may be deep. The second region 320 may have a second diffraction grating region in which a depth of the diffraction grating structure may be shallower than that in the first region 310. The first diffraction grating region and the second diffraction grating region form a resonator with the phase shift portion 319 sandwiched therebetween.

The first region 310 is, because the diffraction grating structure is deep, higher in coupling coefficient κ than the second region 320. In the third example implementation, the normalized coupling coefficient κ1L1 of the first region 310 may be higher than the normalized coupling coefficient κ2L2 of the second region 320 in order to set light intensity of light output from the front facet 40 higher than light intensity of light output from the rear facet 50. Here, “L1” represents an entire length of the first region 310 in the first direction D1. “L2” represents an entire length of the second region 320. The length L1 may be a half or less of an entire length of the semiconductor laser 301. That is, while the main cause of the difference in normalized coupling coefficient KL between the first region 10 and the second region 20 is the difference in the total length of the diffraction grating regions 12A in the first example implementation, the main cause in the third example implementation may be the differences in the depth of the diffraction grating structure and in length between the first region 310 and the second region 320.

The third example implementation differs from the first example implementation also in the material of high resistance elements 330. While the high resistance elements 30 may be the insulating film 14 in the first example implementation, the high resistance elements 330 in the third example implementation may be formed from an insulating material different from an insulating film 314. For example, in a case in which the insulating film 314 is a silicon oxide film, the high resistance elements 330 may be formed of silicon nitride or a resin. The material of the high resistance elements 330 is not limited thereto, and high resistance elements formed from another material may be placed as long as the high resistance elements is higher in resistance than at least the contact layer 13.

The insulating film 314 may be placed on the top surface of the mesa structure 15 except for a part of the top surface. In the second region 320, the second electrode 3 may be in contact with the contact layer 13 in the entire region immediately above the mesa structure 15. That is, the opening ratio of the second region 320 may be 100%. In the first region 310, on the other hand, the high resistance elements 330 may be discretely placed between the second electrode 3 and the contact layer 13. In other words, opening regions (the through-holes 318) in which the second electrode 3 and the contact layer 13 may be in contact with each other may be discretely placed. The first region 310 may be accordingly lower in opening ratio than the second region 320. A preferred opening ratio of the first region 310 is, for example, 20% or more and 50% or less as described in the first example implementation. In the third example implementation as well, the injection current density of the first region 310 may be smaller than the injection current density of the second region 320, and the same effects as those in the first example implementation may be accordingly obtained.

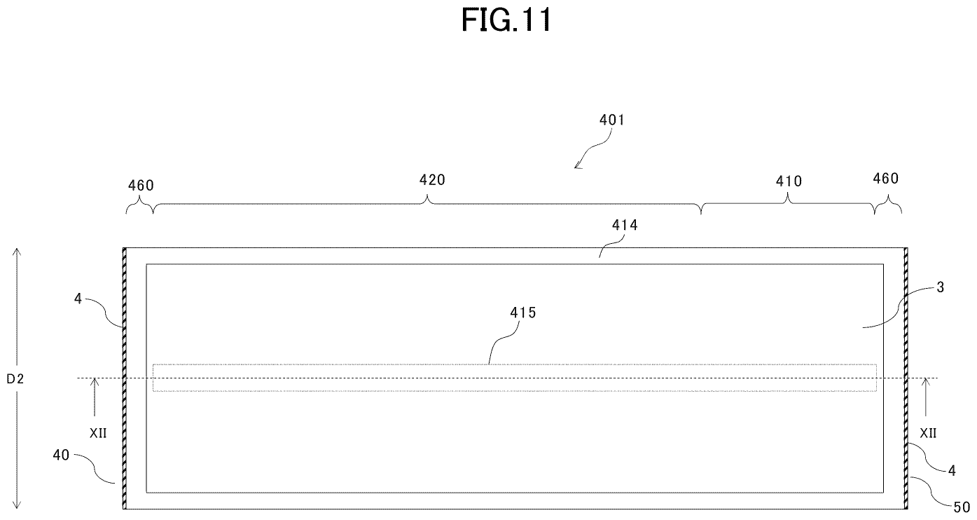

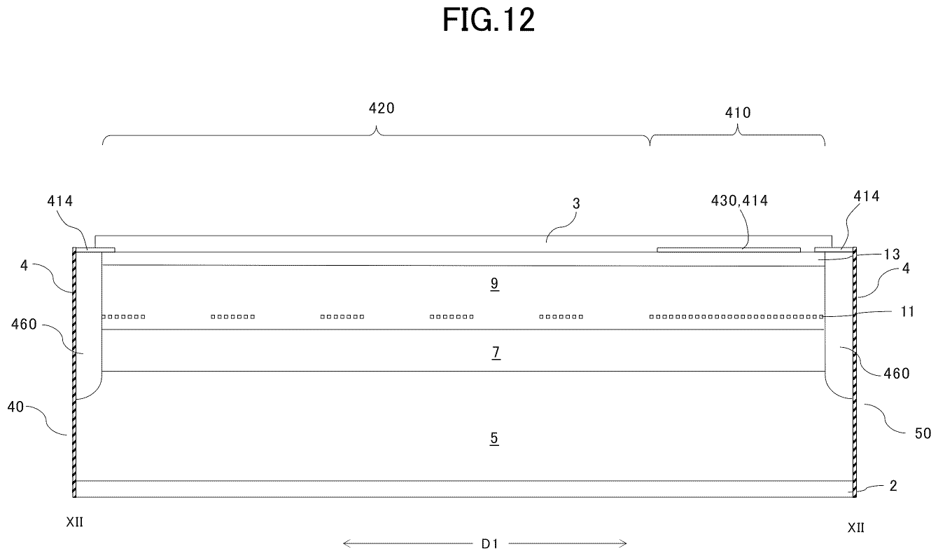

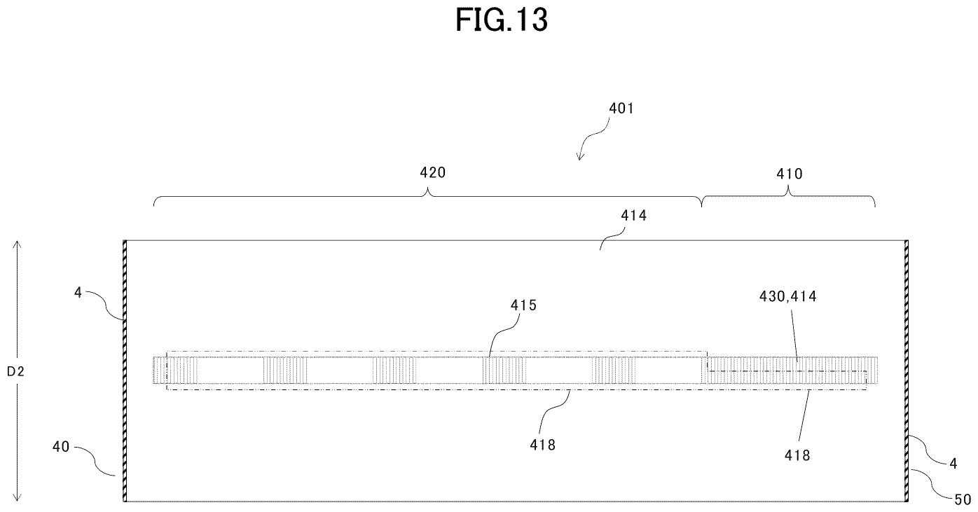

FIG. 11 is a top view of a semiconductor laser 401 according to a fourth example implementation of the present disclosure. FIG. 12 is a schematic sectional view taken along the line XII-XII of FIG. 11. FIG. 13 is another top view of the semiconductor laser 401, and is an explanatory view for illustrating positions of regions included therein. Major differences from the semiconductor laser 1 according to the first example implementation may be differences in shapes of an opening region (a through-hole 418) and a high resistance element 430 of a first region 410, and placement of a window structure 460 between the first region 410 and the rear facet 50 and between a second region 420 and the front facet 40. The rest of the semiconductor multilayer structure may be the same as that in the first example implementation.

The window structure 460 may be formed from a semiconductor material lower in effective refractive index than the active layer included in the core layer 7. For example, the material of the window structure 460 may be the same as the material of the buried layer 17. The window structure 460 may have an effect of reducing light that returns to the core layer 7, and hence improves SMSR characteristics, for example, yield, even more. The window structure 460 may not be included in a mesa structure 415. End faces of the mesa structure 415 in the first direction D1 may be in contact with the window structure 460. The window structure 460 may be placed from one end portion to another end portion of the semiconductor laser 401 in the second direction D2.

In the first region 410, the opening region (through-hole 418) may be substantially quadrangular in plan view. The through-hole 418 may be provided so that a center of the through-hole 418 and a center of the mesa structure 415 are offset from each other in the second direction D2. That is, the through-hole 418 only partially overlaps with the mesa structure 415. The high resistance element 430 (here, an insulating film 414) may be placed in a region in which the through-hole 418 and the mesa structure 415 do not overlap with each other. Thus, the through-hole 418 and the high resistance element 430 may be not required to be alternately arranged in a discrete manner. In the second region 420, the high resistance element 430 may not be placed immediately above the mesa structure 415, except for the vicinity of a connection portion in which the mesa structure 415 may be connected to the window structure 460. The opening ratio of the second region 420 may be accordingly higher compared to the first region 410.

The insulating film 414 may be placed above the window structure 460. The insulating film 414 may be also placed in a part of the first region 410 and a part of the second region 420 to function as the high resistance element 430. In the first region 410, the through-hole 418 may be discretely placed as in the first example implementation. The second electrode 3 may be placed on a part of a top surface of the window structure 460 as well. The effects described above may be obtained also in the fourth example implementation.

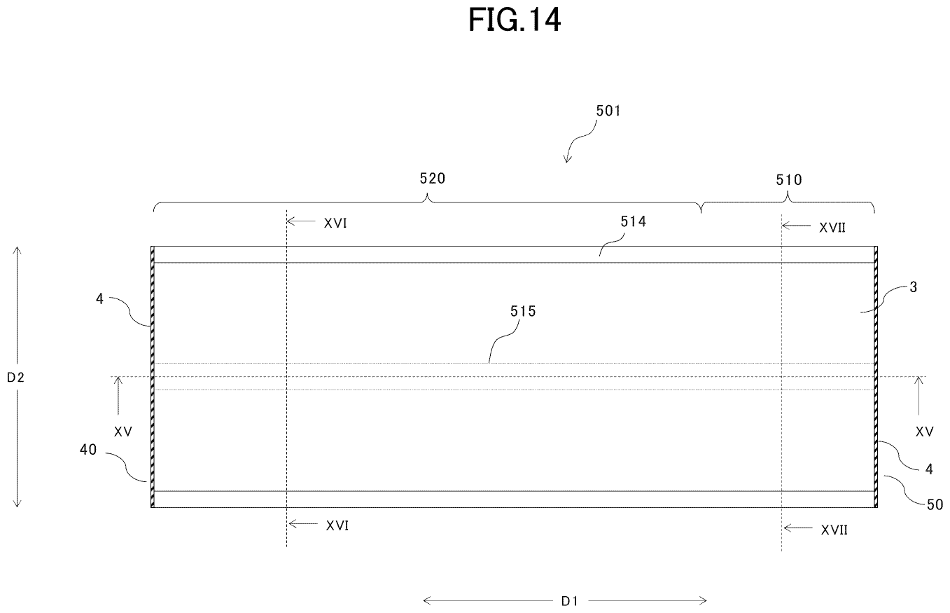

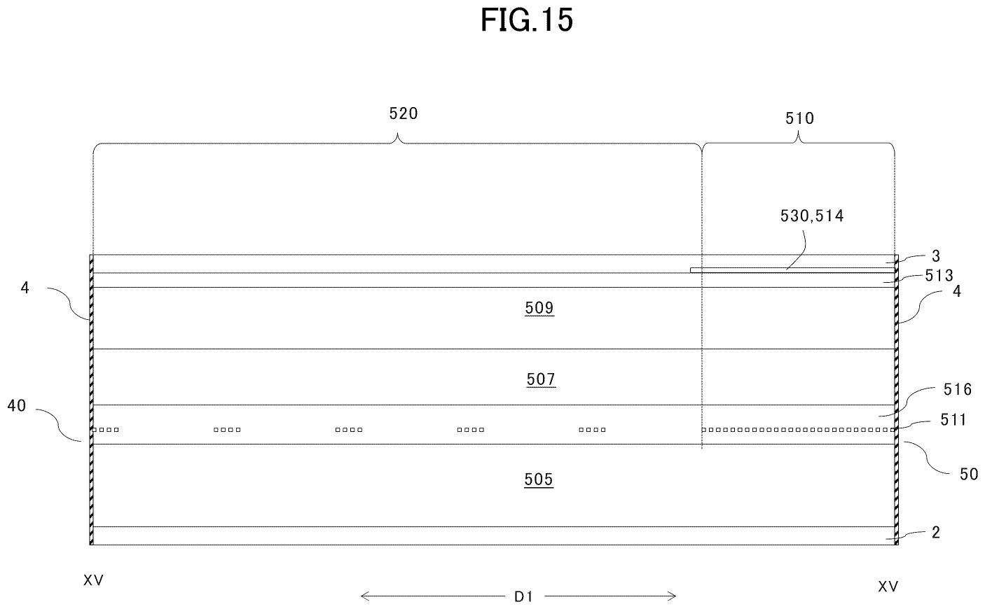

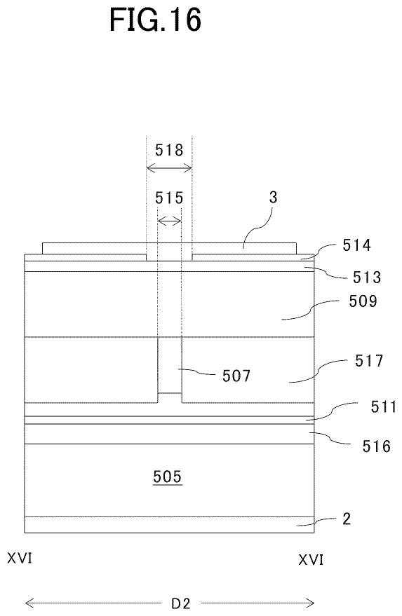

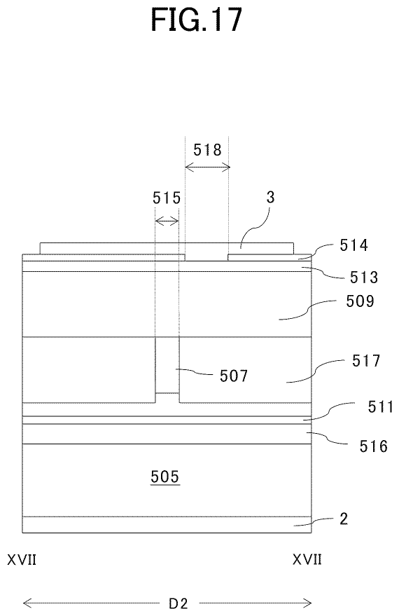

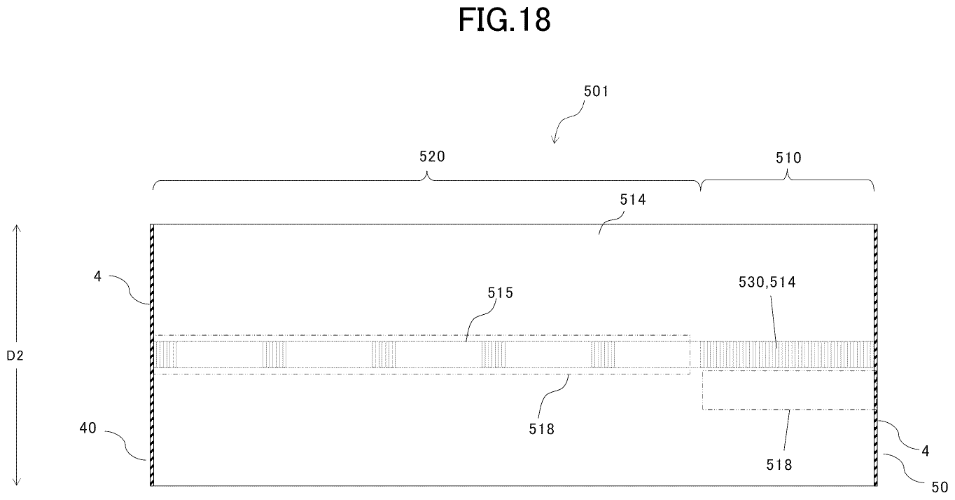

FIG. 14 is a top view of a semiconductor laser 501 according to a fifth embodiment of the present disclosure. FIG. 15 is a schematic sectional view taken along the line XV-XV of FIG. 14. FIG. 16 is a schematic sectional view taken along the line XVI-XVI of FIG. 14. FIG. 17 is a schematic sectional view taken along the line XVII-XVII of FIG. 14. FIG. 18 is another top view of the semiconductor laser 501, and is an explanatory view for illustrating positions of regions included therein. The semiconductor laser 501 may have a planar buried heterostructure (PBH) structure in which a cladding layer 509 of the second-conductivity-type and a contact layer 513 of the second-conductivity-type may be placed wide above a mesa structure 515.

The semiconductor laser 501 may have a semiconductor multilayer structure in which a first-conductivity-type semiconductor layer, an active layer, and a second-conductivity-type semiconductor layer may be grown in the stated order. In the fifth example implementation, semiconductor layers that may be a buffer layer 516 of a first-conductivity-type, a core layer 507, the cladding layer 509 of the second-conductivity-type, and the contact layer 513 of the second-conductivity-type may be grown in the stated order on a substrate 505 of the first-conductivity-type. The substrate 505 and the buffer layer 516 correspond to the first-conductivity-type semiconductor layer. The core layer 507 may be semiconductor layers including at least the active layer. For example, the core layer 507 may be semiconductor layers obtained by growing an optical confinement layer of the first-conductivity-type, the active layer which may be formed from a multiple quantum well layer of an “i” type, and an optical confinement layer of the second-conductivity-type in order from the substrate 505 side. The core layer 507 may include layers other than those semiconductor layers. The active layer may be an n-type semiconductor layer. In the fifth example implementation, the cladding layer 509 and the contact layer 513 form the second-conductivity-type semiconductor layer. A diffraction grating layer 511 may be formed in the buffer layer 516. The semiconductor laser 501 may be a DFB laser. The first-conductivity-type and the second-conductivity-type here may be the n-type and the p-type, respectively, but may be switched with each other. As illustrated in FIG. 16, a part of the buffer layer 516, together with the core layer 507, forms the mesa structure 515. The mesa structure 515 stretches in the first direction D1. The mesa structure 515 may be covered on each side with a semi-insulating semiconductor buried layer 517. The buried layer 517 may be a multilayer of p-type and n-type semiconductor layers. The cladding layer 509 and the contact layer 513 may be placed above the mesa structure 515 and the buried layer 517. The dotted line of FIG. 14 indicates positions of boundaries between the mesa structure 515 and the buried layer 517. The mesa structure 515 may have a width constant in the second direction D2 perpendicular to the first direction D1 in plan view.

The diffraction grating layer 511 may have the same structure as the structure of the diffraction grating layer 11 in the first example implementation, except for being placed below the core layer 507 (on the substrate 505 side). That is, a first region 510 may include a first diffraction grating region which may be the uniform diffraction grating region 12A. A second region 520 may include a plurality of diffraction grating regions 12A (second diffraction grating regions) and a plurality of non-diffraction grating regions 12B. The first diffraction grating region of the first region and the second diffraction grating regions of the second region form a resonator. As described above, phases of the diffraction grating structure that take light path lengths of the first region and the second region into account may be shifted by π-phase shift.

FIG. 18 is a top view of the semiconductor laser 501, and is an explanatory view for illustrating positions of through-holes 518. Illustration of the second electrode 3 may be omitted from FIG. 18 for an explanatory purpose. FIG. 18 is also a view as seen through the diffraction grating layer 511 as if the diffraction grating layer 511 is transparent. The dot-dot-dash lines indicate the positions of opening regions (the through-holes 518). In the second region 520, one of the through-holes 518 may be placed above the mesa structure 515. As illustrated in FIG. 16, the one of the through-holes 518 overlaps with the entirety of the mesa structure 515 in the second direction D2. In the first region 510, on the other hand, another of the through-holes 518 may not be placed immediately above the mesa structure 515, and may be placed in a region offset from the mesa structure 515 (see FIG. 17). In other words, in the first region 510, an opening region may be placed offset from a region immediately above the mesa structure 515 in plan view, and a high resistance element 530 may be placed so as to overlap with the region immediately above the mesa structure 515 in plan view. The PBH structure places the second-conductivity-type semiconductor layer (here, the cladding layer 509 and the contact layer 513) wide above the mesa structure 515 and, accordingly, an electric current injected from the second electrode 3 flows into the mesa structure 515 despite the mesa structure 515 and the another of the through-holes 518 being offset from each other in the second direction D2. However, a distance between the another of the through-holes 518 and a top surface of the mesa structure 515 in the first region 510 may be longer than a distance between the one of the through-holes 518 and the top surface of the mesa structure 515 in the second region 520, with the result that the effective current injection density may be lower in the first region 510.

In the present disclosure, a proportion at which an opening region occupies the region immediately above the mesa structure may be defined as an opening ratio. That is, the opening ratio may not be defined by a ratio of an area in which the mesa structure may be in contact with an electrode. In the fifth example implementation, the opening ratio of the first region 510 in which the opening region does not overlap with the mesa structure 515 in plan view may be 0%. That is, the high resistance element 530 may be placed in the entire region immediately above the mesa structure 515. The second region 520, on the other hand, may have an opening ratio of substantially 100%. In this manner, by setting the opening ratio of the first region which may have a high normalized coupling coefficient lower than the opening ratio of the second region, the effects of the present disclosure may be obtained without requiring the opening region to overlap with the mesa structure.

In the first region 510, the another of the through-holes 518 may partially overlap with the region immediately above the mesa structure 515 as in FIG. 13.

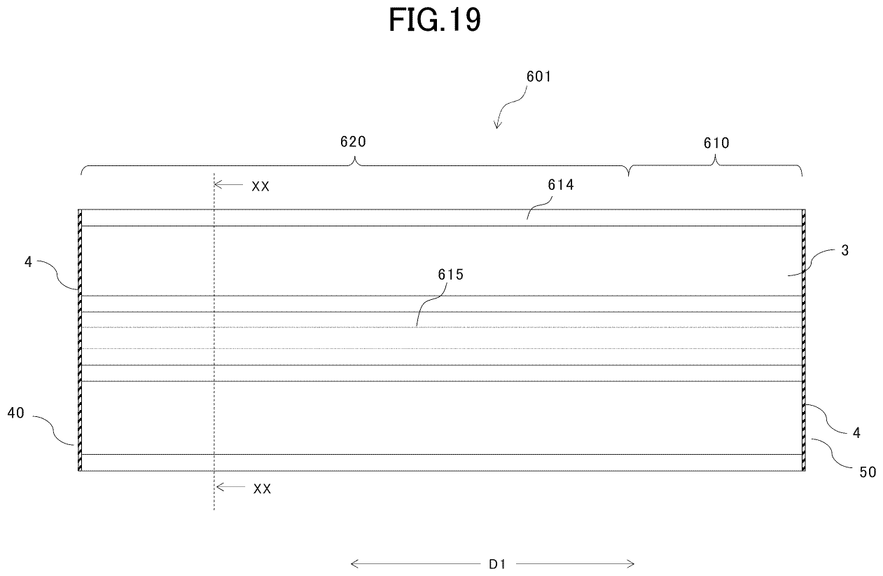

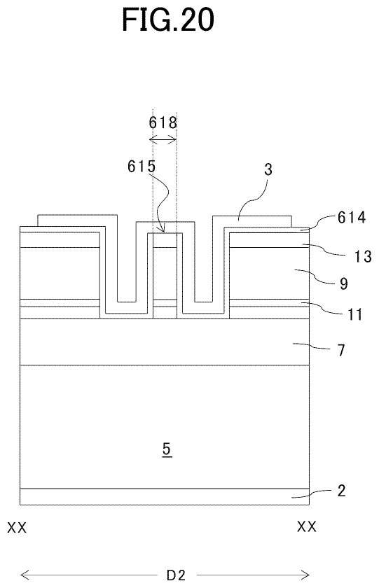

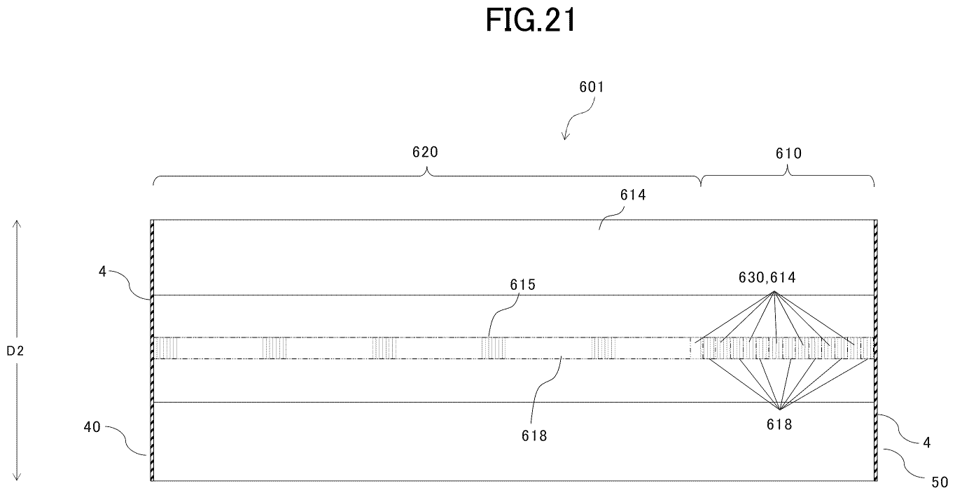

FIG. 19 is a top view of a semiconductor laser 601 according to a sixth example implementation of the present disclosure. FIG. 20 is a schematic sectional view taken along the line XX-XX of FIG. 19. FIG. 21 is another top view of the semiconductor laser 601, and may be an explanatory view for illustrating positions of regions included therein. The semiconductor laser 601 may be a ridge semiconductor laser in which an active layer may not be included in a mesa structure. A semiconductor multilayer structure in the sixth example implementation may be the same as the semiconductor multilayer structure in the first example implementation. A difference may be that a mesa structure 615 does not include the core layer 7 which may include the active layer. In the sixth example implementation, the mesa structure 615 may include the cladding layer 9, the diffraction grating layer 11, and the contact layer 13.

The first region 610 may be higher in normalized coupling coefficient than the second region 620 as in the first example implementation. As illustrated in FIG. 21, the opening ratio of the first region 610 may be lower than the opening ratio of the second region 620. The effects described above may be obtained in the sixth example implementation as well.

The above-mentioned effects may be obtained also by combining the embodiments and modification examples described above. For example, any of a buried semiconductor laser, a PBH semiconductor laser, and a ridge semiconductor laser may be used. Any of placement, the numbers of layers, depths, and the like of diffraction grating structures may be applicable as the structure for varying the normalized coupling coefficient between the first region and the second region. The shapes and positions of the opening region(s) and the high resistance element(s) of the first region may be the shapes and positions in any of the plurality of examples described above. However, the example illustrated in FIG. 18 may be applicable only to a PBH structure. Conversely, application of the other examples to a PBH structure yields the same effects. The diffraction grating layer may be placed above or below the active layer in the stacking direction in which the semiconductor layers may be grown.

The present disclosure improves high power characteristics, high wavelength uniformity, SMSR characteristics, and relative noise intensity characteristics in a semiconductor laser having a mesa structure. The embodiments of the present disclosure achieve this by providing the first region high in normalized coupling coefficient and the second region lower in normalized coupling coefficient than the first region, and setting the opening ratio of the first region lower than the opening ratio of the second region. The low opening ratio gives the first region an injection current density lower than the injection current density of the second region. The first diffraction grating region of the first region and the second diffraction grating region of the second region form a resonator. The phases of the diffraction grating structure that take light path lengths of the first region and the second region into account may be shifted by π-phase shift. The first region may include the first diffraction grating region in which the first refractive index regions and the second refractive index regions for reflecting light of a Bragg wavelength may have the same length and may be alternately arranged. The second region may include the second diffraction grating region in which the first refractive index regions and the second refractive index regions may have the same length and may be alternately arranged, and the non-diffraction grating region through which light of the Bragg wavelength may be transmitted. The non-diffraction grating region may be formed from the first refractive index region alone or the second refractive index region alone. The second region may include a plurality of diffraction grating regions and a plurality of non-diffraction grating regions. The structure for setting the normalized coupling coefficient of the first region higher than the normalized coupling coefficient of the second region may not be limited to the one described above. For example, the normalized coupling coefficient of the first region may be made higher than the normalized coupling coefficient of the second region by setting the number of diffraction grating layers of the first region larger than the number of diffraction grating layers of the second region. This may be achieved also by setting the depth of the diffraction grating structure of the first region deeper than the depth of the diffraction grating structure of the second region. The opening ratio of the first region may be 60% or less, more preferably 20% or more and 50% or less. The high resistance elements may be placed in the non-diffraction grating regions in which no through-holes (openings) may be formed. In the first region, the opening regions and the high resistance elements may be alternately arranged in a direction in which the light travels (the direction in which the mesa structure stretches). The opening region of the first region may be placed so as to only partially overlap with the region immediately above the mesa structure. The high resistance elements may be an insulator such as silicon oxide, silicon nitride, or a resin. The high resistance elements may be not required to cover a region immediately above the mesa structure completely. The planar dimensions of the opening may be reduced by forming portions in which the width of the opening region in the second direction may be small. Low-reflection facet coating films may be formed on the front facet side and the rear facet side of the semiconductor laser. The semiconductor laser may also may have the window structure at each facet. Any of a buried semiconductor laser, a PBH semiconductor laser, and a ridge semiconductor laser may be used. The semiconductor laser of the present disclosure oscillates at a wavelength in the 1.3 μm band or the 1.55 μm band. However, other wavelength bands may be used. The diffraction grating layer may be placed above or below the active layer.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a first-conductivity-type semiconductor layer;
an active layer formed on the first-conductivity-type semiconductor layer;
a second-conductivity-type semiconductor layer formed on the active layer;
a first electrode electrically connected to the first-conductivity-type semiconductor layer;
a second electrode electrically connected to the second-conductivity-type semiconductor layer;
a diffraction grating layer placed on one of the first-conductivity-type semiconductor layer side or the second-conductivity-type semiconductor layer side when viewed from the active layer;
an insulating film placed in a part of a space between the second electrode and the second-conductivity-type semiconductor layer;
a mesa structure including at least one of the active layer or the second-conductivity-type semiconductor layer; and
a first region and a second region in a direction in which the mesa structure stretches,
wherein the diffraction grating layer of the first region includes a first diffraction grating region,
wherein the diffraction grating layer of the second region includes a second diffraction grating region,
wherein the first diffraction grating region and the second diffraction grating region form a resonator,
wherein the first region has a normalized coupling coefficient higher than a normalized coupling coefficient of the second region, and
wherein, in the first region, an electric current supplied from the second electrode to the mesa structure per unit area is smaller than in the second region.

2. The semiconductor laser according to claim 1,
wherein the insulating film includes, in a part of a space above the mesa structure, one or more opening regions in which the second electrode and the second-conductivity-type semiconductor layer are in contact with each other, and
wherein the one or more opening regions occupy a region immediately above the mesa structure at a proportion that is lower in the first region than in the second region.

3. The semiconductor laser according to claim 2, wherein, in the first region, a high resistance element is placed in a non-opening region, the non-opening region being a part of the region immediately above the mesa structure that excludes the one or more opening regions.

4. The semiconductor laser according to claim 3, wherein the one or more opening regions and the non-opening region are alternately arranged in the direction in which the mesa structure stretches.

5. The semiconductor laser according to claim 3, wherein the one or more opening regions have one of a polygonal shape, a circular shape, or an elliptical shape in plan view.

6. The semiconductor laser according to claim 3,
wherein the one or more opening regions are parallelogram in plan view, and
wherein the one or more opening regions have sides inclined in the direction in which the mesa structure stretches.

7. The semiconductor laser according to claim 3, wherein the one or more opening regions have portions in which a width in a direction perpendicular, in plan view, to the direction in which the mesa structure stretches is wide and portions in which the width is narrow.

8. The semiconductor laser according to claim 3, wherein the high resistance element is formed from the insulating film.

9. The semiconductor laser according to claim 3, wherein the high resistance element includes one of silicon oxide, silicon nitride, or a resin.

10. The semiconductor laser according to claim 2, wherein, in the first region, the proportion at which the one or more opening regions occupy the region immediately above the mesa structure is 60% or less.

11. The semiconductor laser according to claim 2, wherein, in the first region, the proportion at which the one or more opening regions occupy the region immediately above the mesa structure is 20% or more and 50% or less.

12. The semiconductor laser according to claim 1,
wherein the diffraction grating layer includes a first refractive index region and a second refractive index region,
wherein the first diffraction grating region of the first region includes a diffraction grating region in which the first refractive index region and the second refractive index region are alternately arranged,
wherein the second region includes a non-diffraction grating region in which one of the first refractive index region alone or the second refractive index region alone is placed, and
wherein the second region includes a plurality of the diffraction grating regions and a plurality of the non-diffraction grating regions.

13. The semiconductor laser according to claim 1,
wherein the diffraction grating layer includes a plurality of diffraction grating layers, and
wherein the first region has the number of diffraction grating layers larger than the number of diffraction grating layers of the second region.

14. The semiconductor laser according to claim 1,
wherein the diffraction grating layer includes two regions different from each other in diffraction grating depth, and
wherein the diffraction grating depth of the first region is deeper than the diffraction grating depth of the second region.

15. The semiconductor laser according to claim 1, wherein, in the direction in which the mesa structure stretches, a low-reflection facet coating film is formed on each facet.

16. The semiconductor laser according to claim 1, wherein, in the direction in which the mesa structure stretches, a window structure lower in refractive index than the active layer is placed between each facet and the mesa structure.

17. The semiconductor laser according to claim 3,
wherein the mesa structure includes the active layer, and
wherein the semiconductor laser further comprises a semiconductor buried layer on each side surface of the mesa structure.

18. The semiconductor laser according to claim 17, wherein the second-conductivity-type semiconductor layer is placed above the mesa structure and the semiconductor buried layer.

19. The semiconductor laser according to claim 18,
wherein, in the first region, the opening region is placed offset, in plan view, from a region immediately above the mesa structure,
wherein, in the first region, the high resistance element is placed so as to overlap, in plan view, with the region immediately above the mesa structure, and
wherein, in the second region, the opening region is placed in the region immediately above the mesa structure.

20. The semiconductor laser according to claim 1, wherein the second electrode is placed so as to stretch across the first region and the second region.
